(19) United States
(12) Patent Application Publication
(10) Pub. No.: US 2015/0288206 A1
(43) Pub. Date: Oct. 8, 2015

(54) SYSTEMS AND METHODS FOR ADAPTIVE FAST-CHARGING FOR MOBILE DEVICES AND DEVICES HAVING SPORADIC POWER-SOURCE CONNECTION

(71) Applicant: StoreDot Ltd., Herzeliya (IL)

(72) Inventors: Daniel Aronov, Netanya (IL); Leonid Krasovitsky, Rishon leZion (IL)

(21) Appl. No.: 14/675,771

(22) Filed: Apr. 1, 2015

Related U.S. Application Data
(60) Provisional application No. 61/976,551, filed on Apr. 8, 2014.

(51) Int. Cl. H02J 7/00; G01R 31/36

(52) U.S. Cl. CPC H02J 7/0044; H02J 7/007; G01R 31/3606

(57) ABSTRACT

The present invention discloses systems and methods for adaptive fast-charging for mobile devices and devices having sporadic power-source connection. Methods include the steps of: firstly determining whether a supercapacitor of a device is charged; upon detecting the supercapacitor is charged, secondly determining whether a battery of the device is charged; and upon detecting the battery is not charged, firstly charging the battery from the supercapacitor. Preferably, the step of firstly determining includes whether the supercapacitor is partially charged, and the step of secondly determining includes whether the battery is partially charged. Preferably, the step of firstly charging is adaptively regulated to perform a task selected from the group consisting of: preserving a lifetime of the battery by controlling a current to the battery, and discharging the supercapacitor in order to charge the battery. Preferably, the discharging enables the supercapacitor to be subsequently recharged.

### CROSS REFERENCE TO RELATED APPLICATIONS

This patent application claims priority under 35 U.S.C. §119(e) to U.S. Provisional Patent Application No. 61/976,551 filed Apr. 8, 2014, which is hereby incorporated by reference in its entirety.

### FIELD AND BACKGROUND OF THE INVENTION

The present invention relates to systems and methods for adaptive fast-charging for mobile devices and devices having sporadic power-source connection.

Modem electronic appliances are becoming ubiquitous for personal as well as business use. It cannot be overstated that with the evolution of such devices, mobility has emerged as a key driver in feature enhancement for technological innovation. While the rapid advancement of low power-consumption processors and flash-memory devices have enabled such mobility to reach new levels of real-world productivity, further development is significantly hampered by the rather slow progress made in battery technology. The proliferation of smart phones, tablets, laptops, ultrabooks, and the like (acquiring smaller and smaller form factors) has made this issue even more abundantly apparent as consumers are eager to have longer and longer device usage times between recharge cycles, without adding heft to the weight and footprint of such devices.

Furthermore, electrical and electronic components that don't fall under the mobile rubric are also in need of extended usage solutions. Such components include devices having sporadic power-source connection (e.g., backup emergency sentinels, remotely-stationed telecommunication repeaters, electric vehicle console communicators, as well as off-shore communication, control, and positioning devices).

The demands of such applications vary widely, for example, in voltage or power level, but all are preferably served by lightweight, power-storage devices which can rapidly and consistently provide high energy density over long time spans, and can be quickly recharged to operational energy levels. To date, such extensive mobile energy needs are being met in part by one of two available types of power-storage devices: rechargeable batteries (e.g., lithium-ion intercalation systems) or supercapacitors (e.g., Faradic pseudo-capacitive type, non-Faradic double-layer reaction types, or hybrid types).

To meet the growing demand in portable electronic devices and devices having sporadic power-source connection, energy storage devices with high specific energy, high power density, long cycle life, low cost, and a high margin of safety must be employed.

Currently, the dominant energy storage device remains the battery, particularly the lithium-ion battery. Lithium-ion batteries power nearly every portable electronic device, as well as almost every electric car, including the Tesla Model S and the Chevy Volt. Batteries store energy electrochemically, in which chemical reactions release electrical carriers that can be extracted into an electrical circuit. During discharge, the energy-containing lithium ions travel from a high-energy anode material through a separator to a low-energy cathode material. The movement of the lithium ions releases energy, which is extracted into an external circuit.

During battery charging, energy is used to move the lithium ions back to the high-energy anode compound. The charge and discharge process in batteries is a slow process, and can degrade the chemical compounds inside the battery over time. A key bottleneck in achieving enhanced performance is the limited fast-charging ability of any standard battery. Rapid charging causes accelerated degradation of the battery constituents, as well as a potential fire hazard due to a localized, over-potential build-up and increased heat generation.

For example, Li-ion batteries have the highest energy density of rechargeable batteries available, but typically suffer from low power by virtue of reversible Coulombic reactions occurring at both electrodes, involving charge transfer and ion diffusion in bulk electrode materials. Since both diffusion and charge transfer are slow processes, power delivery as well as the recharge time of Li-ion batteries is kinetically limited. As a result, batteries have a low power density, and lose their ability to retain energy throughout their lifetime due to material degradation.

On the other extreme, electrochemical double-layer capacitors (EDLCs) or ultracapacitors are, together with pseudocapacitors, part of a new type of electrochemical capacitors called supercapacitors (hereinafter referred to as SCs), which store energy through accumulation of ions on an electrode surface, have limited energy storage capacity, but very high power density. In such SCs, energy is stored electrostatically on the surface of the material, and does not involve a chemical reaction. As a result, SCs can be charged quickly, leading to a very high power density, and do not lose their storage capabilities over time. SCs can last for millions of charge/discharge cycles without losing energy storage capability. The main shortcoming of SCs is their low energy density, meaning that the amount of energy SCs can store per unit weight is very small, particularly when compared to batteries.

The most intuitive approach to combine high energy and high power density within a single device is to combine different types of energy storage sources. So far, such hybrid power-source devices involving SCs and batteries have mainly been explored in view of parallel connection (i.e., an SC is being used as a power supply, while the battery is used as an energy source, which supplies energy both to the load and to the SC, which in turn, should be charged at all times). The contribution of components to the total stored charge is not optimal, due to the minimal use of the SC, and the higher degradation of the battery due to the additional charging of the SC.

In the prior art, Kan et al. published findings (Journal of Power Sources, 162(2), 971-974, 2006) analyzing combinations of rechargeable batteries and capacitors in storage media of photovoltaic-powered products. In such applications, the focus of the study was to reduce power cycling of the batteries by utilizing a well-defined recharge duty cycle.

Buiel et al. published findings at the Capacitor and Resistor Technology Symposium (CARTS International 2013) on development of ultrathin ultracapacitors for enhanced lithium batteries in portable electronic applications. The focus of the study was to extend the usable energy stored on lithium batteries by compensating for voltage droop during GSM radio pulses by employing an SC to discharge to the lithium battery when the low-voltage cutoff of the main battery is reached. Similarly, this was also partly the subject of International Patent Publication No. WO/2006/112698 for a rechargeable power supply.

It would be desirable to have systems and methods for adaptive fast-charging for mobile devices and devices having sporadic power-source connection. Such systems and methods would, inter alia, overcome the various limitations mentioned above.

### SUMMARY

It is the purpose of the present invention to provide systems and methods for adaptive fast-charging for mobile devices and devices having sporadic power-source connection.

It is noted that the term “exemplary” is used herein to refer to examples of embodiments and/or implementations, and is not meant to necessarily convey a more-desirable use-case. Similarly, the terms “preferred” and “preferably” are used herein to refer to an example out of an assortment of contemplated embodiments and/or implementations, and is not meant to necessarily convey a more-desirable use-case. Therefore, it is understood from the above that “exemplary” and “preferred” may be applied herein to multiple embodiments and/or implementations.

Preferred embodiments of the present invention enable adaptive fast-charging of mobile devices and devices having sporadic power-source connection by incorporating high-energy SCs in combination with rechargeable batteries, allowing for higher system power, while preserving the energy density of the battery in a device-compatible form factor.

Features of such adaptive fast-charging systems and methods include, inter alia the following aspects.
Fast charging (due to SC properties)
Adaptive charging intervals (via control of battery charging characteristics)
Standard working time
High energy density (due to intrinsic battery properties)
High power density (due to intrinsic SC properties)
Battery lifetime improvement (via control of battery charging characteristics)
High current input allowed
Adaptive battery charging by controlling the current
Can't be overcharged (SC can't be overcharged, and battery charging is controlled)
Can't be overheated (SC can't be overheated, and battery charging is controlled)
Low self-discharge (energy is accumulated in battery, with low intrinsic discharge properties)

Therefore, according to the present invention, there is provided a method for adaptive fast-charging for mobile devices and devices having sporadic power-source connection, the method including the steps of: (a) firstly determining whether a supercapacitor of a device is charged; (b) upon detecting the supercapacitor is charged, secondly determining whether a battery of the device is charged; and (c) upon detecting the battery is not charged, firstly charging the battery from the supercapacitor.

Preferably, the step of firstly determining includes determining whether the supercapacitor is partially charged, and the step of secondly determining includes determining whether the battery is partially charged.

Preferably, the step of firstly charging is adaptively regulated to perform at least one task selected from the group consisting of: preserving a lifetime of the battery by controlling a current to the battery, and discharging the supercapacitor in order to charge the battery.

Most preferably, the discharging enables the supercapacitor to be subsequently recharged.

Preferably, the method further including the steps of: (d) prior to the step of firstly determining, initially determining whether an external charger is connected to the device; and (e) upon detecting the external charger is connected to the device, secondly charging the supercapacitor and/or the battery from the external charger.

Most preferably, the method further including the step of: (f) upon detecting the external charger is not connected to the device, supplying energy to the device from the supercapacitor and/or the battery.

According to the present invention, there is provided a system for adaptive fast-charging for mobile devices and devices having sporadic power-source connection, the system including: (a) a supercapacitor charging controller for firstly determining whether a supercapacitor of a device is charged; and (b) a battery charging controller for secondly determining whether a battery of the device is charged; wherein, upon detecting the supercapacitor is charged and upon detecting the battery is not charged, the supercapacitor charging controller is configured for firstly charging the battery from the supercapacitor.

Preferably, the firstly determining includes determining whether the supercapacitor is partially charged, and the secondly determining includes determining whether the battery is partially charged.

Preferably, the firstly charging is adaptively regulated to perform at least one task selected from the group consisting of: preserving a lifetime of the battery by controlling a current to the battery, and discharging the supercapacitor in order to charge the battery.

Most preferably, the discharging enables the supercapacitor to be subsequently recharged.

Preferably, the supercapacitor charging controller is further configured for: (i) prior to the firstly determining, initially determining whether an external charger is connected to the device; and (ii) upon detecting the external charger is connected to the device, secondly charging the supercapacitor and/or the battery from the external charger.

Most preferably, the supercapacitor charging controller is further configured for: (iii) upon detecting the external charger is not connected to the device, supplying energy to the device from the supercapacitor and/or the battery.

According to the present invention, there is provided a non-transitory computer-readable medium, having computer-readable code embodied on the non-transitory computer-readable medium, the computer-readable code having program code for adaptive fast-charging for mobile devices and devices having sporadic power-source connection, the computer-readable code including: (a) program code for firstly determining whether a supercapacitor of a device is charged; (b) program code for, upon detecting the supercapacitor is charged, secondly determining whether a battery of the device is charged; and (c) program code for, upon detecting the battery is not charged, firstly charging the battery from the supercapacitor.

Preferably, the firstly determining includes determining whether the supercapacitor is partially charged, and the secondly determining includes determining whether the battery is partially charged.

Preferably, the firstly charging is adaptively regulated to perform at least one task selected from the group consisting of: preserving a lifetime of the battery by controlling a current to the battery, and discharging the supercapacitor in order to charge the battery.

Most preferably, the discharging enables the supercapacitor to be subsequently recharged.

Preferably, the computer-readable code comprising further includes: (d) program code for, prior to the firstly determining, initially determining whether an external charger is connected to the device; and (e) program code for, upon detecting the external charger is connected to the device, secondly charging the supercapacitor and/or the battery from the external charger.

Most preferably, the computer-readable code comprising further includes: (f) program code for, upon detecting the external charger is not connected to the device, supplying energy to the device from the supercapacitor and/or the battery.

These and further embodiments will be apparent from the detailed description that follows.

### BRIEF DESCRIPTION OF THE DRAWINGS

The present invention is herein described, by way of example only, with reference to the accompanying drawing, wherein:

FIG. 1 is a simplified high-level schematic diagram of the device architecture for adaptive fast-charging for mobile devices and devices having sporadic power-source connection, according to preferred embodiments of the present invention;

FIG. 2 is a simplified flowchart of the major process steps of an SC controller for adaptive fast-charging for mobile devices and devices having sporadic power-source connection, according to preferred embodiments of the present invention;

FIG. 3 is a simplified flowchart of the major process steps of a battery controller for adaptive fast-charging for mobile devices and devices having sporadic power-source connection, according to preferred embodiments of the present invention;

FIG. 4 is a simplified flowchart of the major process steps of a device interface controller for adaptive fast-charging for mobile devices and devices having sporadic power-source connection, according to preferred embodiments of the present invention;

FIG. 5A is a graph of a typical Li-ion battery charge curve, as known in the prior art;

FIG. 5B is a graph of a typical Li-ion battery discharge curve, as known in the prior art;

FIG. 6A is a graph of a typical SC charge curve, as known in the prior art;

FIG. 6B is a graph of a typical SC discharge curve, as known in the prior art;

FIG. 7 is a graph of a FlashBattery charge/discharge simulation in accordance with the simulation parameters of Table 1, according to preferred embodiments of the present invention;

FIG. 8 is a graph of a FlashBattery charge/discharge simulation in accordance with the simulation parameters of Table 2, according to preferred embodiments of the present invention;

FIG. 9 is a graph of a FlashBattery charge/discharge simulation in accordance with the simulation parameters of Table 3, according to preferred embodiments of the present invention;

FIG. 10 is a graph of a FlashBattery charge/discharge simulation in accordance with the simulation parameters of Table 4, according to preferred embodiments of the present invention;

FIG. 11 is a graph of a FlashBattery charge/discharge simulation in accordance with the simulation parameters of Table 5, according to preferred embodiments of the present invention.

### DESCRIPTION OF THE PREFERRED EMBODIMENTS

The present invention relates to systems and methods for adaptive fast-charging for mobile devices and devices having sporadic power-source connection. The principles and operation for providing such systems and methods, according to the present invention, may be better understood with reference to the accompanying description and the drawings.

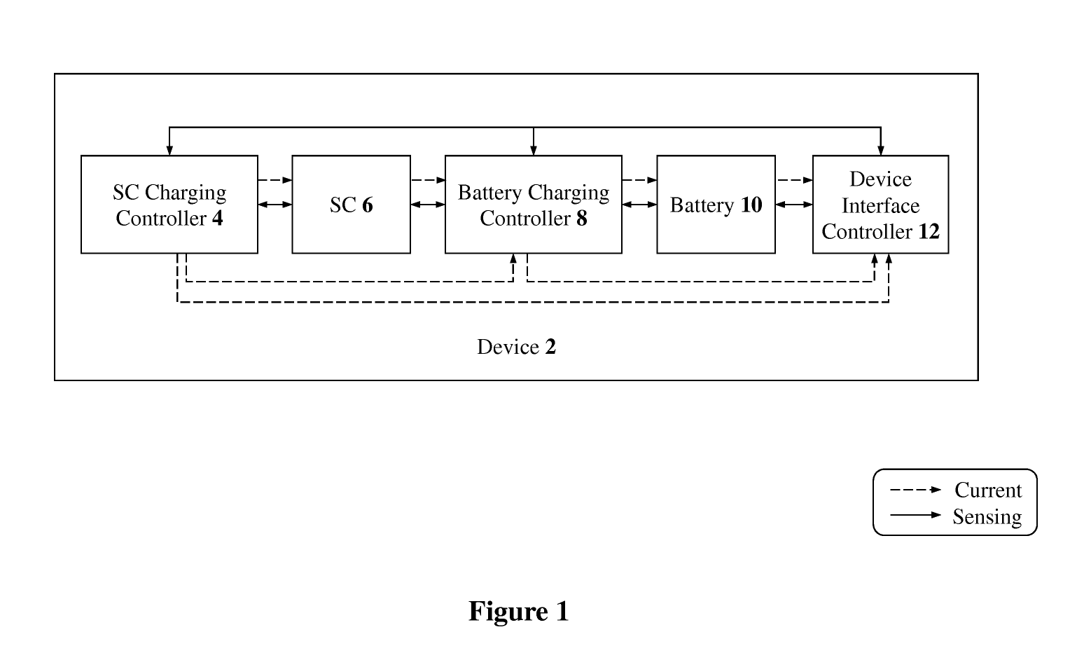

Referring to the drawings, FIG. 1 is a simplified high-level schematic diagram of the device architecture for adaptive fast-charging for mobile devices and devices having sporadic power-source connection, according to preferred embodiments of the present invention. A device 2 (i.e., mobile device or a device having sporadic power-source connection) is shown having a SC charging controller 4, an SC 6, a battery charging controller 8, a rechargeable battery 10, and a device interface controller 12 operationally connected to each other. SC charging controller 4 and battery charging controller 8 each include a charge-sensing element (not shown in FIG. 1) for detecting the level of charge on SC 6 and battery 10, respectively. Charging current flow and charge sensing among the various components are depicted by arrows in FIG. 1.

SC charging controller 4 is responsible for charging preferences of SC 6 and/or battery 10. SC 6 allows for fast charging for operation of device 2, and is responsible for power and energy accumulation. Battery charging controller 8 is responsible for battery charging preferences and current input from SC 6 and/or from SC charging controller 4. Battery 10 is responsible for energy and power accumulation. Device interface controller 12 is responsible for energy and power input preferences for device 2 (e.g., laptop, electric car, and cell-phone).

The device architecture of FIG. 1 enables an optimal contribution of SC 6 and battery 10 to performance of device 2. Such device architecture provides a dramatic improvement of battery power capabilities by decoupling power and energy performance, thus increasing the cycle life of the battery. Fast-charging capability is achieved largely by the high power capacity of SC 6, which can be charged using high current flowing from an external charger (not shown in FIG. 1). After charging of SC 6 is complete, the external charger may be disconnected. Then, battery 10 is charged via the charging current from SC 6. The charge/discharge current flow between SC 6 and battery 10 may be modified according to the indication of SC charging controller 4, battery charging controller 8, and device interface controller 12, thus giving rise to a higher cycle life of device 2.

SC 6 includes an electrolyte and electrodes. The electrodes may be made from activated carbon powders, carbon nanotubes, carbon nanofibres, carbon aerogels, metal oxides, conductive polymers (such as polyaniline, polypyrrole, polythiophene). In addition, several SCs may be connected in series or/and parallel to form a composite component represented as SC 6.

SC charging controller 4 allows high DC current or pulse current inputs, and enables customized charging preferences (e.g., slow and fast discharge options) between SC 6 and battery 10 when an external charger is connected, while monitoring the accumulated charge on each of SC 6 and battery 10.

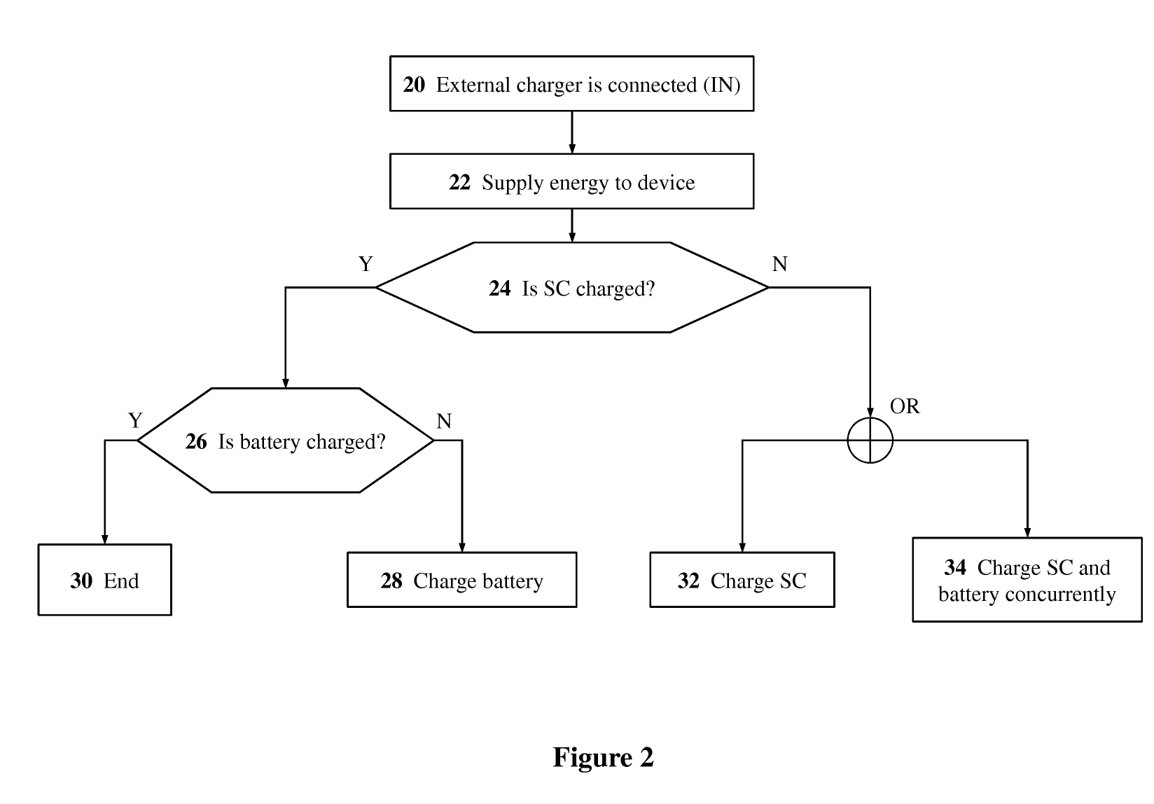

FIG. 2 is a simplified flowchart of the major process steps of an SC controller for adaptive fast-charging for mobile devices and devices having sporadic power-source connection, according to preferred embodiments of the present invention. When an external charger is connected to a power source (IN) (Step 20), energy is supplied from the external charger to device 2 without using the stored energy in SC 6 and/or battery 10 (Step 22). The energy and power needed for device 2 is drawn from the charger itself, but can be also be supplied from SC 6 and/or battery 10.

The charge-sensing element of SC charge controller 4 then determines whether SC 6 is fully charged (Step 24). SC 6 and/or battery 10 receive their charging current from the external charger. The charging current may be continuous current or pulsed. If SC 6 is fully charged, the charge-sensing element of battery charge controller 8 then determines whether battery 10 is fully charged (Step 26). If battery 10 is not fully charged, energy is supplied from the external charger via charging current to battery 10 (Step 28). If battery 10 is fully charged, energy is not supplied from the external charger to battery 10, and the process ends (Step 30). The external charger may only supply the needed energy and power to device 2.

If SC 6 is not fully charged in Step 24, then energy is supplied from the external charger via charging current to SC 6 (Step 32), or supplied concurrently to both SC 6 and battery 10 (Step 34).

Battery charging controller 8 allows adjustable current and/or voltage output, and enables customized charging preferences (e.g., slow and fast discharge options) of battery 10 when the external charger is not connected to a power source (OUT), while monitoring the accumulated charge on each of SC 6 and battery 10. Battery charging controller 8 also serves as an input current/voltage controller via, for example, DC-DC converters (e.g., step-up or step-down transformers).

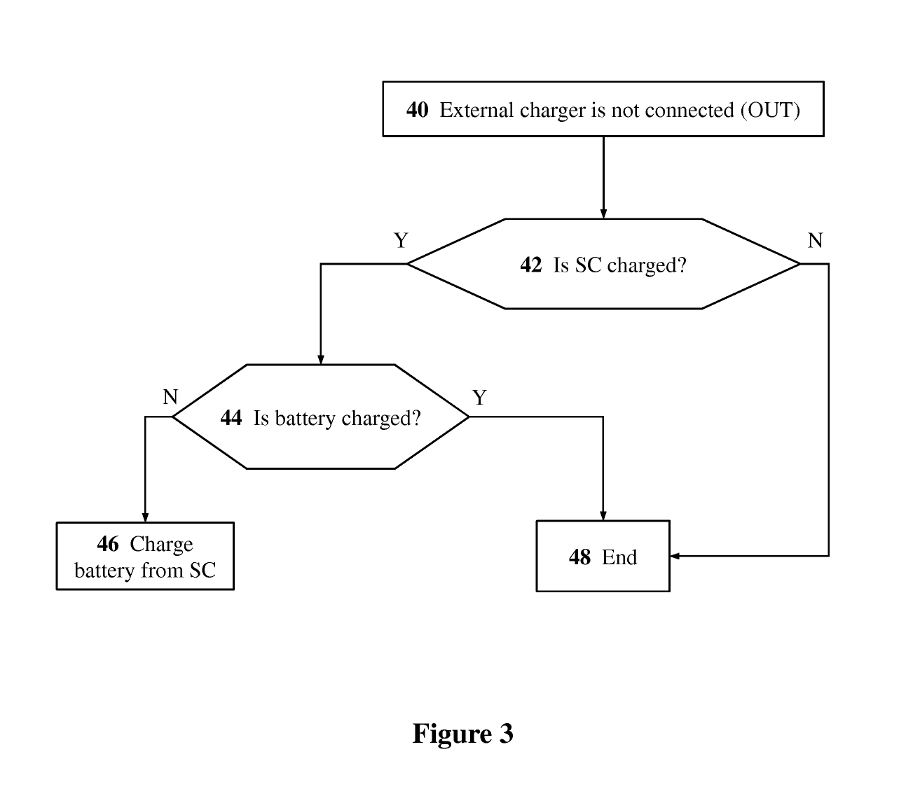

FIG. 3 is a simplified flowchart of the major process steps of a battery controller for adaptive fast-charging for mobile devices and devices having sporadic power-source connection, according to preferred embodiments of the present invention. When an external charger is not connected to a power source (OUT) (Step 40), the charge-sensing element of SC charge controller 4 determines whether SC 6 is fully charged (Step 42). If SC 6 is even partially charged, the charge-sensing element of battery charge controller 8 then determines whether battery 10 is fully charged (Step 44). If battery 10 is not fully charged, battery 8 is charged via charging current from SC 6 (Step 46). If battery 10 is fully charged, or if SC is not charged at all, then the process ends (Step 48).

Device interface controller 12 is responsible for managing and prioritizing the energy and power demands of the load of device 2 with regard to the energy and power supplies via current/voltage regulation.

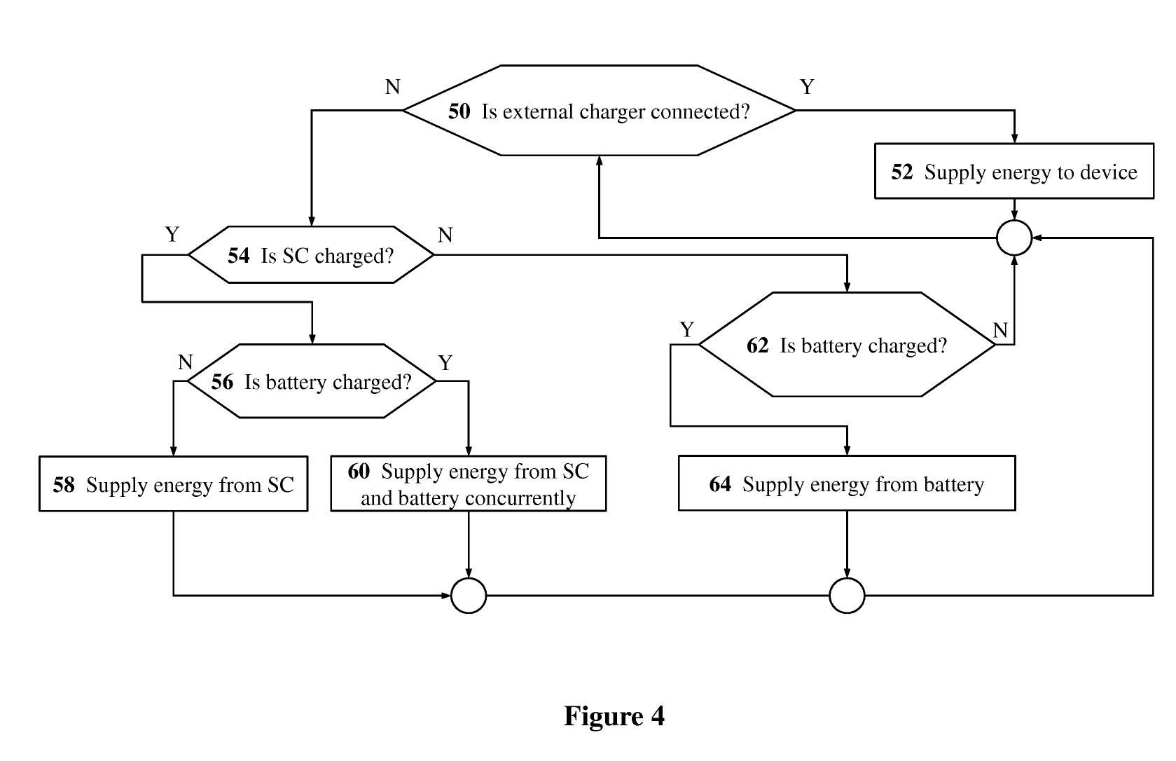

FIG. 4 is a simplified flowchart of the major process steps of a device interface controller for adaptive fast-charging for mobile devices and devices having sporadic power-source connection, according to preferred embodiments of the present invention. Device interface controller 12 determines whether an external charger is connected (Step 50). If an external charger is connected to a power source (IN), then energy and power is supplied from the external charger to device 2 for operation and/or for charging SC 6 and/or battery 10 if they are not fully charged (Step 52), and the process returns to Step 50.

If an external charger is not connected to a power source (OUT), then the charge-sensing element of SC charge controller 4 determines whether SC 6 is even partially charged (Step 54). If SC 6 is even partially charged, then the charge-sensing element of battery charge controller 8 determines whether battery 10 is even partially charged (Step 56). If battery 10 is not charged at all, then power is supplied solely from SC 6 via charging current to device 2 (Step 58), and the process returns to Step 50. If battery 10 is even partially charged in Step 56, then energy and power is supplied concurrently from both SC 6 and battery 10 to device 2 (Step 60), and the process returns to Step 50.

If SC 6 is not charged at all in Step 54, then the charge-sensing element of battery charge controller 8 determines whether battery 10 is even partially charged (Step 62). If battery 10 is even partially charged, then energy and power is supplied solely from battery 10 (Step 64), and the process returns to Step 50. If battery 10 is not charged at all, then the process returns to Step 50.

Simulations

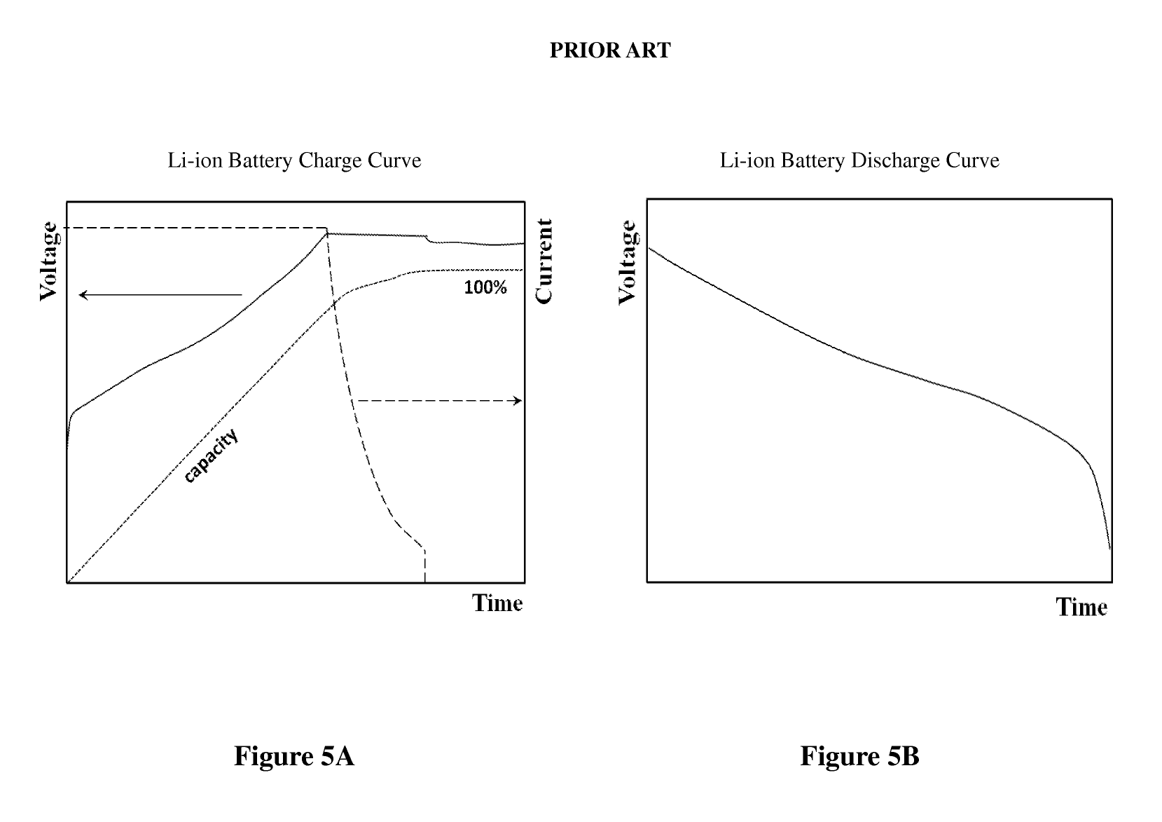

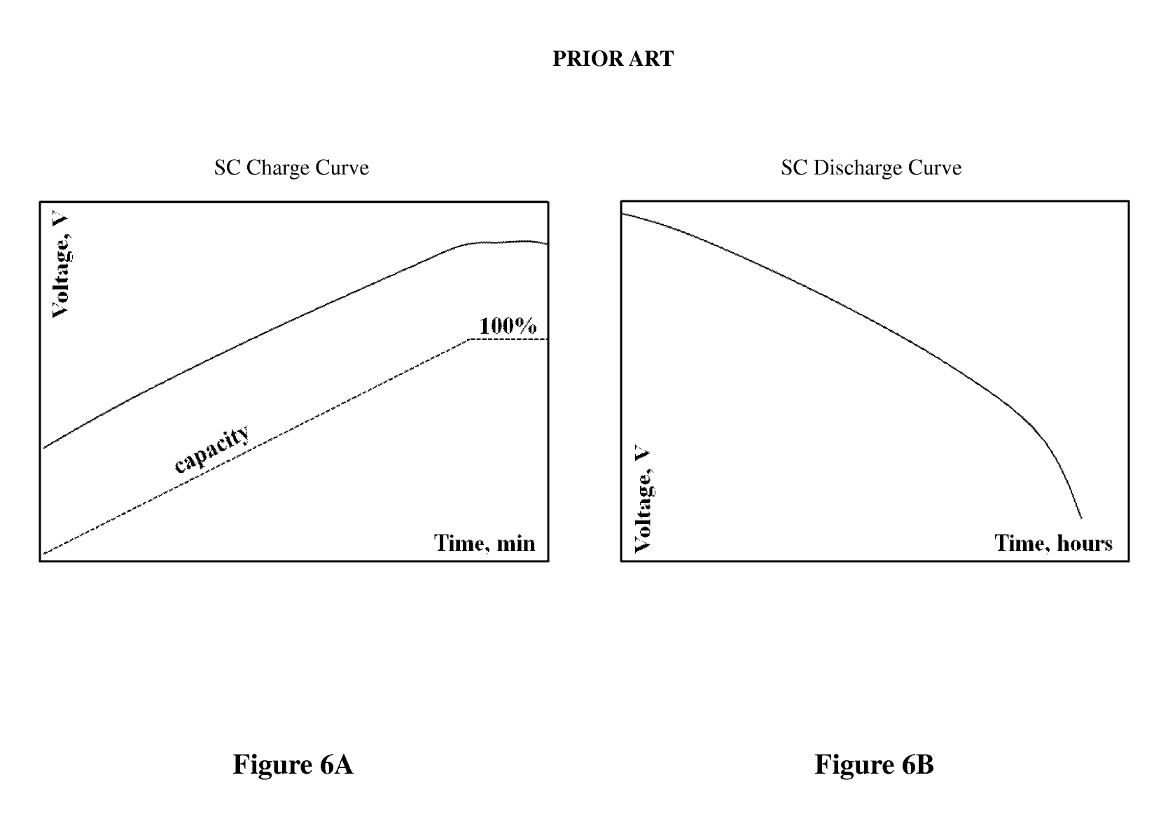

As a reference, FIG. 5A is a graph of a typical Li-ion battery charge curve, and FIG. 5B is a graph of a typical Li-ion battery discharge curve, as known in the prior art. FIG. 6A is a graph of a typical SC charge curve, and FIG. 6B is a graph of a typical SC discharge curve, as known in the prior art.

Unlike batteries, SCs may be charged and discharged at very high current, resulting in fast charge/discharge rates. SCs may be charged by constant current. A DC-to-DC constant current regulator is the simplest form of active charging. Either a buck or boost regulator may be used depending on the application. A buck regulator is the preferred topology due to the continuous output charge current.

The present invention relates to systems and methods for adaptive fast-charging for mobile devices and devices having sporadic power-source connection. Charge/discharge simulations were conducted with a FlashBattery system as follows.
SC charging controller—output voltage: up to 10V; output current: up to 30 A (e.g., LinearTechnology, LT3741)
SC—capacitance C=180 F; voltage V=10.8V; energy E=3 Wh; charge time: @30 A, ˜60 sec.
Battery charging controller—input voltage: min 200 mV; output voltage: up to 4.5V; output current: up to 1000 mA; Li-ion rechargeable battery; capacity 1500 mAh; voltage V=3.7V; charge time: @500 mA, ˜200 min or @ 1000 mA, ˜100 min (LinearTechnology, LTC 3105)
Device interface controller—current switch between SC and battery.
Device—constant load: 200 mA (i.e., average current for 3G mobile service for cell-phone with 2100 mAh battery and charge for 11 hrs.)

Using FlashBattery parameters listed above, the following simulation data was obtained: (1) SC fully charged within 60 sec.; (2) SC discharged down to 0.5% capacity; and (3) battery fully charged within 100 or 200 minutes using 1000 mA and 500 mA, respectively. Details of the simulation parameters are provided below in the following Tables.

TABLE 1
Charge/discharge simulation parameters of FlashBattery system for 60-sec.
charge, with battery charged in rapid mode using 1000 mA (Simulation #1).

| | SC Charging | Battery Charging | Device Interface | |
|---|---|---|---|---|
| Time | Controller | Controller | Controller | SC/Battery |
| t = 0 | External | Battery charging: | Load current from | SC = 0%, |
| | charger: IN | OFF | external charger | Batt = 0% |
| t = 60 sec | External | Battery charging: | Load current from | SC = 100%, |
| | charger: OUT | ON - 1000 mA | SC: 200 mA | Batt = 0% |
| t~36 min | External | Battery charging: | Load current from | SC~0% |
| | charger: OUT | OFF | battery: 200 mA | Batt~40% |
| t > 36 min | External | Battery charging: | Load current from | Batt < 40% |
| | charger: OUT | OFF | battery: 200 mA | |

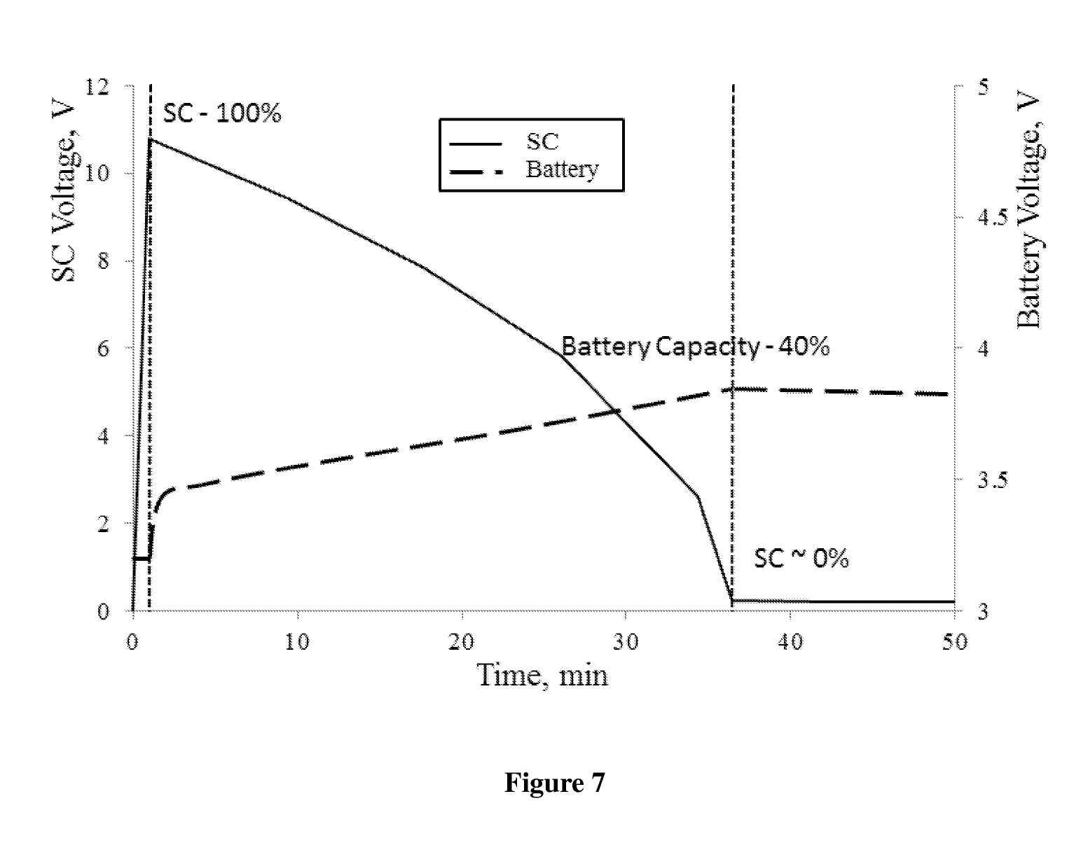

FIG. 7 is a graph of a FlashBattery charge/discharge simulation in accordance with the simulation parameters of Table 1, according to preferred embodiments of the present invention.

TABLE 2
Charge/discharge simulation parameters of FlashBattery
system, 100% charged for both SC and battery, with battery
charged in rapid mode using 1000 mA (Simulation #2).

| | SC Charging | Battery Charging | Device Interface | |
|---|---|---|---|---|
| Time | Controller | Controller | Controller | SC/Battery |
| t = 0 | External | Battery charging: | Load current from | SC = 0%, |
| | charger: IN | OFF | external charger | Bat = 0% |
| t = 60 sec | External | Battery charging: | Load current from | SC = 100%, |
| | charger: OUT | ON - 1000 mA | SC - 200 mA | Bat = 0% |
| t~36 min | External | Battery charging: | Load current from | SC~0% |
| | charger: OUT | OFF | battery - 200 mA | Batt~40% |
| t~60 min | External | Battery charging: | Load current from | SC~0% |
| | charger: IN | OFF | external charger | Batt~35% |
| t~61 min | External | Battery charging: | Load current from | SC = 100% |
| | Charger “OUT” | ON - 1000 mA | SC - 200 mA | Batt~35% |
| t~97 min | External | Battery charging: | Load current from | SC~0% |
| | charger: OUT | OFF | Battery - 200 mA | Batt~75% |
| t~120 min | External | Battery charging: | Load current from | SC~0% |
| | charger: IN | OFF | external charger | Batt~70% |
| t~121 min | External | Battery charging: | Load current from | SC = 100% |
| | charger: OUT | ON - 1000 mA | SC - 200 mA | Batt~70% |
| t~125 min | External | Battery Charging: | Load current from | SC~80% |
| | charger “OUT” | ON - constant | SC - 200 mA | Batt~80% |
| | | voltage mode | | |
| | | (<1000 mA) | | |
| t~152 min | External | Battery Charging: | Load current from | SC~60% |
| | charger: OUT | OFF | SC - 200 mA | Batt = 100% |
| t~153 min | External | Battery Charging: | Load current from | SC~60% |
| | charger: IN | OFF | external charger | Batt = 100% |
| t~153 min | External | Battery charging: | Load current from | SC = 100% |
| | charger: OUT | OFF | SC - 200 mA | Batt = 100% |
| t > 153 min | External | Battery charging: | Load current from | SC < 100% |
| | charger: OUT | OFF | SC - 200 mA | Batt = 100% |

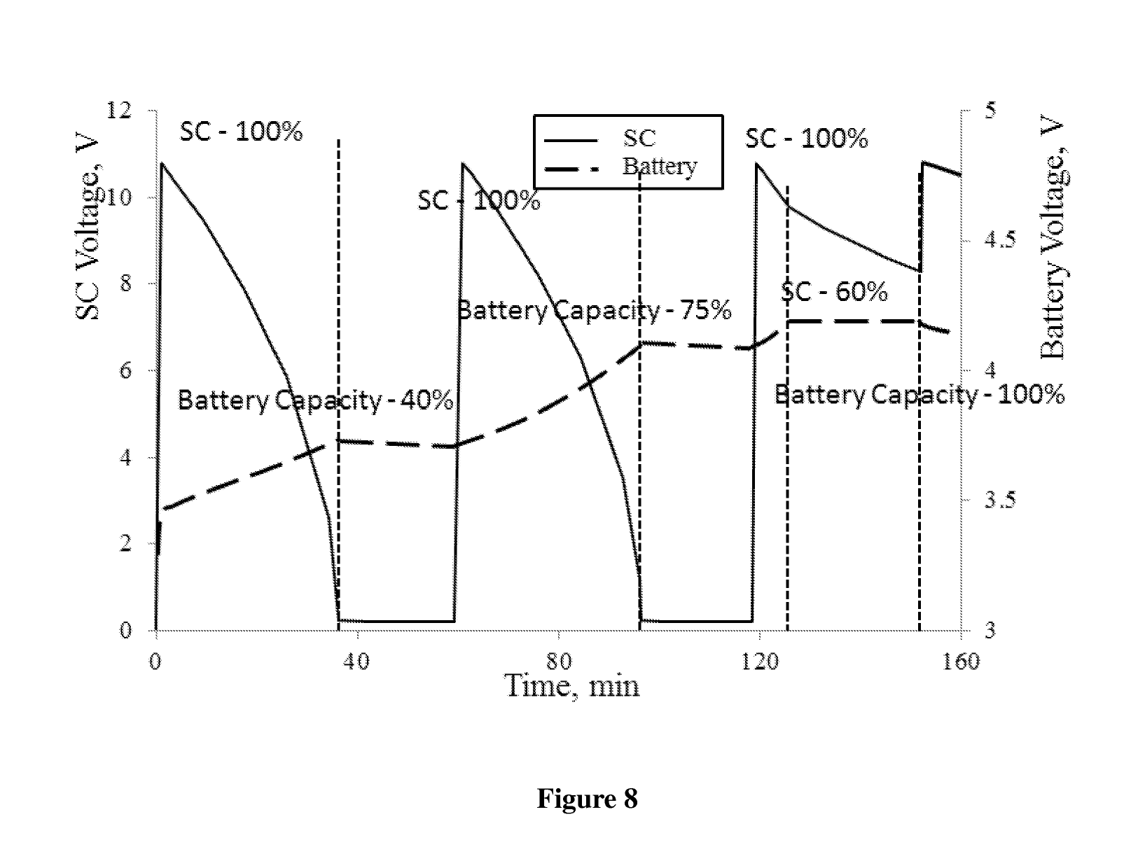

FIG. 8 is a graph of a FlashBattery charge/discharge simulation in accordance with the simulation parameters of Table 2, according to preferred embodiments of the present invention.

TABLE 3
Charge/discharge simulation parameters of FlashBattery system
for 60-sec. charge, operation on battery, with battery charged
in rapid mode using 1000 mA (Simulation #3).

| | SC Charging | Battery Charging | Device Interface | |
|---|---|---|---|---|
| Time | Controller | Controller | Controller | SC/Battery |
| t = 0 | External | Battery charging: | Load current from | SC = 0%, |
| | charger: IN | OFF | external charger | Batt = 0% |
| t = 60 sec | External | Battery charging: | Load current from | SC = 100%, |
| | charger: OUT | ON - 300 mA | SC - 200 mA | Batt = 0% |
| t~36 min | External | Battery charging: | Load current from | SC~0% |
| | charger: OUT | OFF | battery - 200 mA | Batt~40% |
| t~216 min | External | Battery charging: | Load current from | SC~0% |
| | charger: IN | OFF | external charger | Batt = 0% |
| t~217 min | External | Battery charging: | Load Current from | SC = 100%, |
| | charger: OUT | ON - 300 mA | SC - 200 mA | Batt = 0% |
| t~253 min | External | Battery charging: | Load current from | SC~0% |
| | charger: OUT | OFF | battery - 200 mA | Batt~40% |
| t > 253 min | External | Battery charging: | Load current from | SC~0% |
| | charger: OUT | OFF | battery - 200 mA | Batt < 40% |

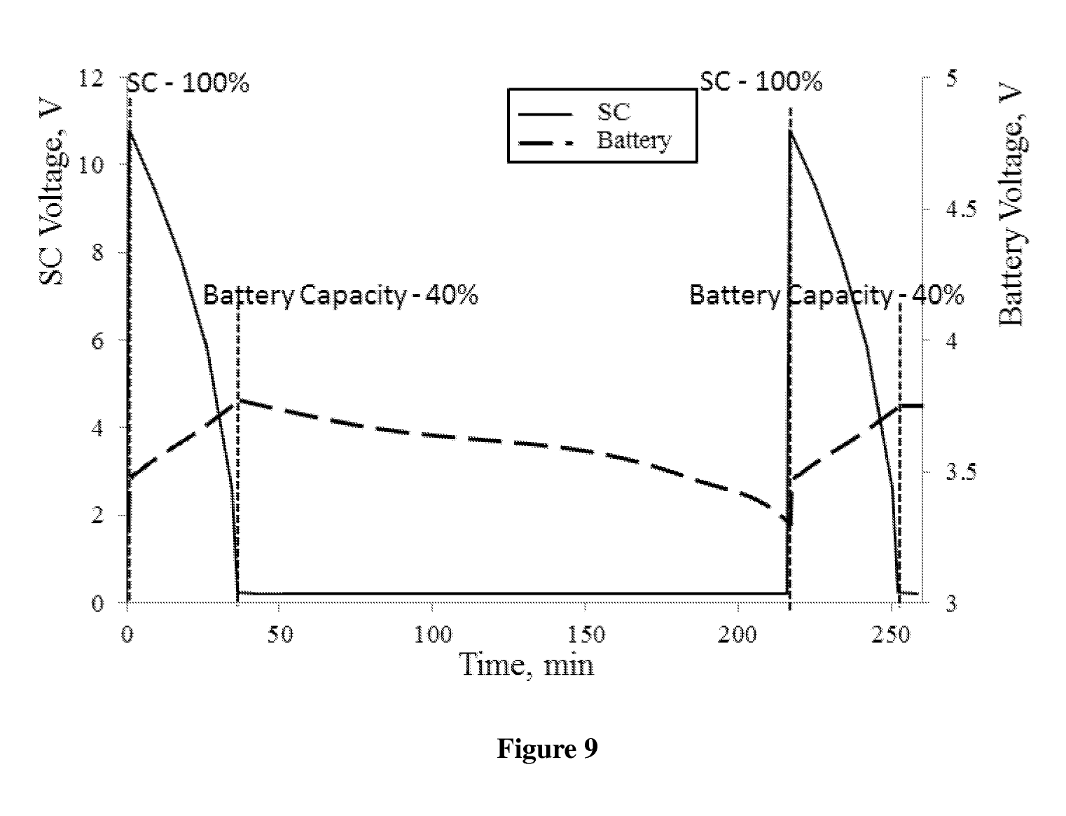

FIG. 9 is a graph of a FlashBattery charge/discharge simulation in accordance with the simulation parameters of Table 3, according to preferred embodiments of the present invention.

TABLE 4
Charge/discharge simulation parameters of FlashBattery system
for low-current battery charge from SC, with battery charged
in low-current mode using 500 mA (Simulation #4).

| | SC Charging | Battery Charging | Device Interface | |
|---|---|---|---|---|
| Time | Controller | Controller | Controller | SC/Battery |
| t = 0 | External | Battery charging: | Load current from | SC = 0%, |
| | charger: IN | OFF | external charger | Batt = 0% |
| t = 60 sec | External | Battery charging: | Load current from | SC = 100%, |
| | charger: OUT | ON - 500 mA | SC - 200 mA | Batt = 0% |
| t~60 min | External | Battery charging: | Load current from | SC~0% |
| | charger: OUT | OFF | battery - 200 mA | Batt~35% |
| t > 60 min | External | Battery charging: | Load current from | SC~0% |
| | charger: OUT | OFF | battery - 200 mA | Batt < 35% |

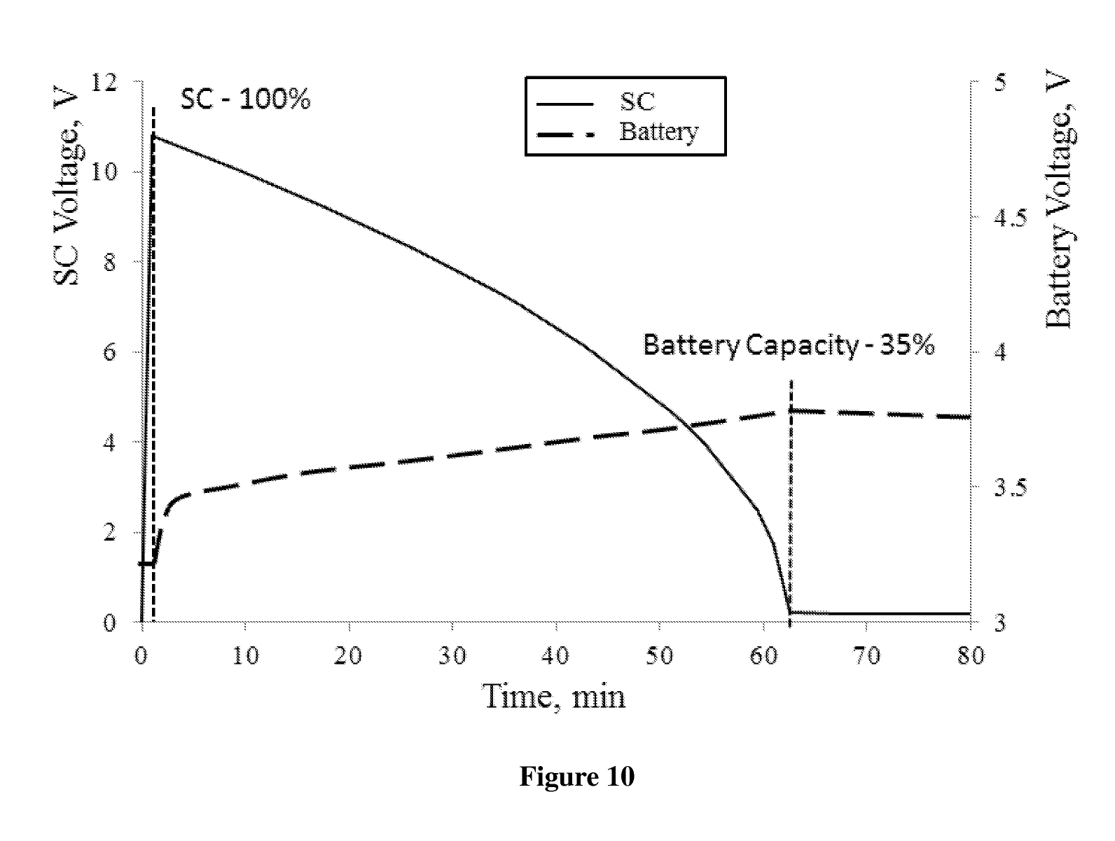

FIG. 10 is a graph of a FlashBattery charge/discharge simulation in accordance with the simulation parameters of Table 4, according to preferred embodiments of the present invention. The low-current mode may be applied during standby time when a device is idle in order to save battery lifetime.

TABLE 5
Charge/discharge simulation parameters of FlashBattery
system, 100% charged from external charger, with battery
charged in rapid mode using 1000 mA (Simulation #5).

| | SC Charging | Battery Charging | Device Interface | |
|---|---|---|---|---|
| Time | Controller | Controller | Controller | SC/Battery |
| t = 0 | External | Battery charging: | Load current from | SC = 0%, |
| | charger: IN | OFF | charger - 200 mA | Batt = 0% |
| t = 60 sec | External | Battery charger: | Load current from | SC = 100%, |
| | charger: IN | ON - 1000 mA | charger - 200 mA | Batt = 0% |
| t = 101 min | External | Battery charging: | Load current from | SC = 100%, |
| | charger: OUT | OFF | SC - 200 mA | Batt = 100% |
| t > 101 min | External | Battery charging: | Load current from | SC < 100%, |
| | charger: OUT | OFF | SC - 200 mA | Batt = 100% |

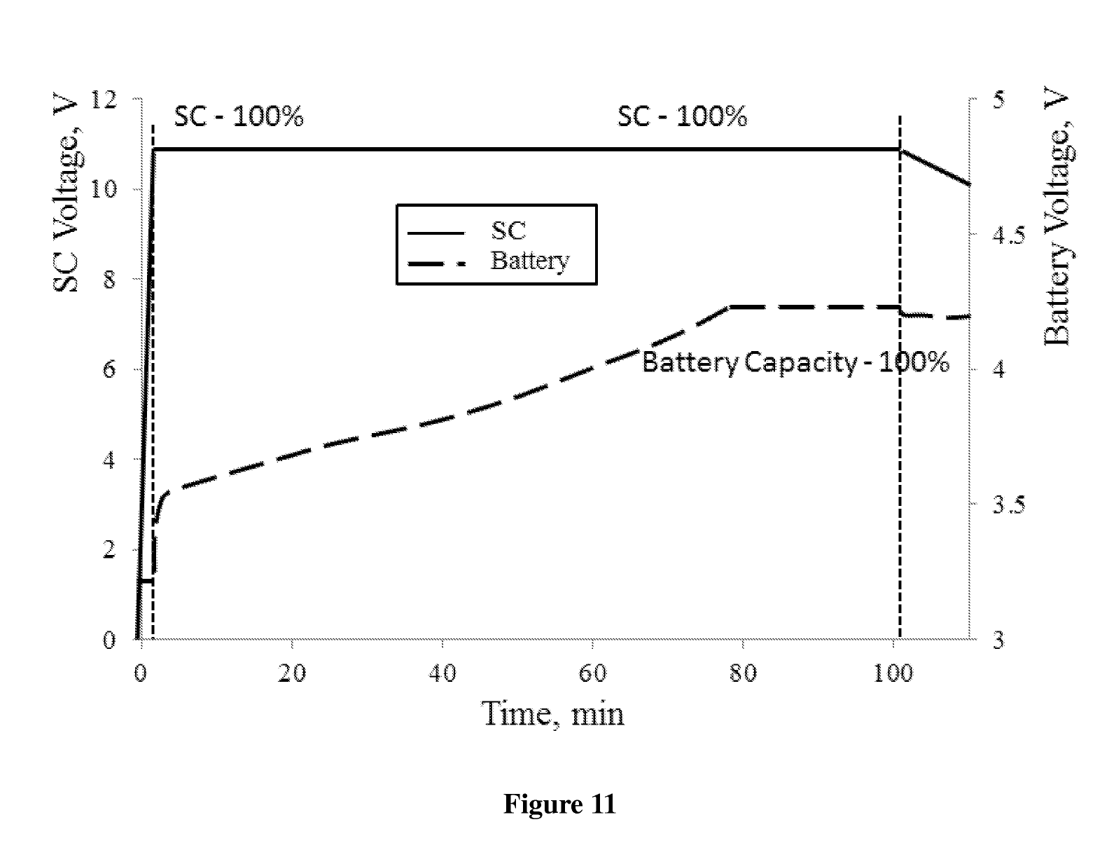

FIG. 11 is a graph of a FlashBattery charge/discharge simulation in accordance with the simulation parameters of Table 5, according to preferred embodiments of the present invention.

Simulation Summary

Table 6 compares the results from the FlashBattery system with a standard cell-phone battery.

TABLE 6
Charge/discharge simulation parameters of FlashBattery
system with combination SC and battery configuration.

| | Standard Cell-phone | | SC (3 Wh) & | |
|---|---|---|---|---|
| Performance Parameters | battery (2500 mAh) | | Battery (1500 mAh) | |
| Charging time | 2.5-4 | hrs. | 60 | sec. |
| Operation time | ~11 | his. | ~3.5 | hrs. |
| (200 mA constant load) | | | | |
| Recharge interval | <11 | hrs. | ~35 min. | |
| | | | (after SC discharge) | |
| Operation time after recharge | <11 | hrs. | 3.5-11 | hrs. |
| (200 mA constant load) | | | | |

In such a case, the FlashBattery system provides device power from an SC and battery with flexible and convenient adaptive fast-charging capabilities, resulting in long operation time. Moreover, smart battery charging is enabled by controlling the current, allowing adaptation of the system to user requirements.

While the present invention has been described with respect to a limited number of embodiments, it will be appreciated that many variations, modifications, and other applications of the present invention may be made.

What is claimed is:

1. A method for adaptive fast-charging for mobile devices and devices having sporadic power-source connection, the method comprising the steps of:
(a) firstly determining whether a supercapacitor of a device is charged;
(b) upon detecting said supercapacitor is charged, secondly determining whether a battery of said device is charged; and
(c) upon detecting said battery is not charged, firstly charging said battery from said supercapacitor.

2. The method of claim 1, wherein said step of firstly determining includes determining whether said supercapacitor is partially charged, and wherein said step of secondly determining includes determining whether said battery is partially charged.

3. The method of claim 1, wherein said step of firstly charging is adaptively regulated to perform at least one task selected from the group consisting of: preserving a lifetime of said battery by controlling a current to said battery, and discharging said supercapacitor in order to charge said battery.

4. The method of claim 3, wherein said discharging enables said supercapacitor to be subsequently recharged.

5. The method of claim 1, the method further comprising the steps of:
(d) prior to said step of firstly determining, initially determining whether an external charger is connected to said device; and
(e) upon detecting said external charger is connected to said device, secondly charging said supercapacitor and/or said battery from said external charger.

6. The method of claim 5, the method further comprising the step of:
(f) upon detecting said external charger is not connected to said device, supplying energy to said device from said supercapacitor and/or said battery.

7. A system for adaptive fast-charging for mobile devices and devices having sporadic power-source connection, the system comprising:
(a) a supercapacitor charging controller for firstly determining whether a supercapacitor of a device is charged; and
(b) a battery charging controller for secondly determining whether a battery of said device is charged;
wherein, upon detecting said supercapacitor is charged and upon detecting said battery is not charged, said supercapacitor charging controller is configured for firstly charging said battery from said supercapacitor.

8. The system of claim 7, wherein said firstly determining includes determining whether said supercapacitor is partially charged, and wherein said secondly determining includes determining whether said battery is partially charged.

9. The system of claim 7, wherein said firstly charging is adaptively regulated to perform at least one task selected from the group consisting of: preserving a lifetime of said battery by controlling a current to said battery, and discharging said supercapacitor in order to charge said battery.

10. The system of claim 9, wherein said discharging enables said supercapacitor to be subsequently recharged.

11. The system of claim 7, wherein said supercapacitor charging controller is further configured for:
(i) prior to said firstly determining, initially determining whether an external charger is connected to said device; and
(ii) upon detecting said external charger is connected to said device, secondly charging said supercapacitor and/or said battery from said external charger.

12. The system of claim 11, wherein said supercapacitor charging controller is further configured for:
(iii) upon detecting said external charger is not connected to said device, supplying energy to said device from said supercapacitor and/or said battery.

13. A non-transitory computer-readable medium, having computer-readable code embodied on the non-transitory computer-readable medium, the computer-readable code having program code for adaptive fast-charging for mobile devices and devices having sporadic power-source connection, the computer-readable code comprising:
(a) program code for firstly determining whether a supercapacitor of a device is charged;
(b) program code for, upon detecting said supercapacitor is charged, secondly determining whether a battery of said device is charged; and
(c) program code for, upon detecting said battery is not charged, firstly charging said battery from said supercapacitor.

14. The computer-readable medium of claim 13, wherein said firstly determining includes determining whether said supercapacitor is partially charged, and wherein said secondly determining includes determining whether said battery is partially charged.

15. The computer-readable medium of claim 13, wherein said firstly charging is adaptively regulated to perform at least one task selected from the group consisting of:
preserving a lifetime of said battery by controlling a current to said battery, and discharging said supercapacitor in order to charge said battery.

16. The computer-readable medium of claim 15, wherein said discharging enables said supercapacitor to be subsequently recharged.

17. The computer-readable medium of claim 13, the computer-readable code comprising further comprising:
(d) program code for, prior to said firstly determining, initially determining whether an external charger is connected to said device; and
(e) program code for, upon detecting said external charger is connected to said device, secondly charging said supercapacitor and/or said battery from said external charger.

18. The computer-readable medium of claim 17, the computer-readable code comprising further comprising:
(f) program code for, upon detecting said external charger is not connected to said device, supplying energy to said device from said supercapacitor and/or said battery.
